(19) United States
(12) Patent Application Publication
(10) Pub. No.: US 2017/0346439 A1
(43) Pub. Date: Nov. 30, 2017

(54) Apparatus for Mounting Conduit to Solar Panel Arrays

(71) Applicant: Ironridge, Inc., Hayward, CA (US)

(72) Inventors: William Pereira, Phoenix, AZ (US); Bryan Lester, Phoenix, AZ (US); Shawn Meine, Phoenix, AZ (US)

(73) Assignee: IronRidge, Inc., Hayward, CA (US)

(21) Appl. No.: 15/610,428

(22) Filed: May 31, 2017

Related U.S. Application Data
(60) Provisional application No. 62/343,809, filed on May 31, 2016.

(51) Int. Cl. H02S 40/30; H02S 30/10; H02S 20/26; H05K 7/14; H02S 20/23

(52) U.S. Cl. CPC H02S 40/30; H05K 7/14; H02S 20/23; H02S 20/26; H02S 30/10

(57) ABSTRACT

In various representative aspects, an apparatus for securing conduit to solar panel arrays that are typically installed on roof structures. More specifically, the assembly comprises a mount that is coupled to a solar panel module or a rail-less wire conduit structure for securing wire conduit alongside the perimeter of an array of solar panel modules.

### BACKGROUND OF INVENTION

### Field of the Invention

The present invention relates generally to an apparatus for securing conduit to solar panel arrays that are typically installed on roof structures. More specifically, the assembly comprises a mount that is coupled to a solar panel module or a rail-less wire conduit structure for securing wire conduit alongside the perimeter of an array of solar panel modules. A method of installation is also disclosed.

### Description of the Related Art

Any discussion of the prior art in the specification should in no way be considered as an admission that the prior art is widely known or forms part of common general knowledge in the field.

Installing a solar panel array on a roof can be challenging. One difficult aspect of the process is installing conduit that stores the wiring used as part of the solar panel array installation, and doing it in a manner that minimizes the visibility of the conduit on the roof in a simple and effective manner.

A typical conduit acts as a rigid passage to protect and assist in routing electrical wiring for the solar panel array. The most common conduit sizes for residential solar installations are ¾-inch and 1-inch conduits and are made from either metal (EMT) or PVC plastic.

There are three common installation techniques to install electrical wiring conduit. The first technique is a roof-mounted conduit as shown in FIG. 1. This technique mounts the conduit 120 to a roof 110 using wood, metal, or plastic blocks 100 coupled with fasteners or clamps 105 as shown.

The second technique mounts the conduit 120 directly to the roof 110 using flashings 130 as shown in FIG. 2. This technique typically includes a small mount 100 that is secured to the flashing 130 that also uses a mounting clip 150 to secure the conduit 120 to the mount 100 This technique is cumbersome to install and requires several extra parts as well. Another variation of the technique shown in FIG. 2 is the use of a conduit mount 170 that simply sits directly on top of a roof as shown in FIG. 3. The use of these mounts 170 keeps the conduit 120 open and viewable on the roof, which is not desirable.

The third technique utilizes a rail-mounted installation as shown in FIG. 4. This technique is used in rail-mounted solar panel arrays. The conduit 120 is mounted directly to the solar panel array structure 180 as shown.

Examples of standard conduit mounts 192, 194, 196, and 198 are shown in FIG. 5. Each of these mounts require a support structure to secure the mount to a roof.

The known prior art does not enable conduit to be secured directly to solar panel frames. The present invention overcomes these limitations and offers a solution that requires minimal parts and is easy to install, use, and manufacture.

### SUMMARY OF THE INVENTION

The invention is summarized below only for purposes of introducing embodiments of the invention. The ultimate scope of the invention is to be limited only to the claims that follow the specification.

It is an object of the present invention to provide a mounting assembly for securing a conduit to a solar panel frame.

It is a further object of the present invention for the mounting assembly to have an upper end and a lower end.

It is a further object of the present invention for the bottom end to comprise a conduit retainer.

It is a further object of the present invention for the upper end to comprise a first mouth for receiving a flange of a solar panel mounting frame.

It is a further object of the present invention for the upper end to further comprise a second mouth beneath the first mouth for receiving a terminating end of a wire management structure that is attached to a rail-less solar panel mounting structure.

It is a further object of the present invention for the upper end to further comprise a top surface coupled to the first mouth that forms a resilient structure.

It is a further object of the present invention that the resilient structure is s-shaped.

It is a further object of the present invention that the conduit retainer is generally c-shaped.

It is a further object of the present invention that the first and second mouths are resilient.

A person with ordinary skill in the relevant art would know that any shape or size of the elements described below may be adopted. Any combinations of suitable number, shape, and size of the elements described below may be used. Also, any materials suitable to achieve the object of the current invention may be chosen as well.

### BRIEF DESCRIPTION OF THE DRAWINGS

A more complete understanding of the present invention may be derived by referring to the detailed description and claims when considered in connection with the following illustrative figures. In the following figures, like reference numbers refer to similar elements and steps throughout the figures.

FIG. 1 illustrates a perspective view of a prior art roof-mounted conduit assembly.

FIG. 2 illustrates a top view of a perspective view of the prior art roof-mounted conduit assembly that utilizes a flashing.

FIG. 3 illustrates a perspective view of a pair of prior art conduit roof mounts.

FIG. 4 illustrates a perspective view of a prior art conduit mount secured to a solar panel rail array.

FIG. 5 illustrates a perspective view of several prior art conduit mounts.

FIG. 6 illustrates a top view illustrating a typical rail-less solar panel array structure.

FIG. 7 illustrates front and rear perspective views of an exemplary solar panel array conduit mount.

FIG. 8 illustrates is a side view of a rail-less solar panel mount that includes a wire management apparatus with the conduit mount being utilized in two ways.

FIG. 9 illustrates a perspective view showing the conduit mount secured to a solar panel frame.

FIG. 10 illustrates a rear perspective view of the conduit mount secured to a solar panel frame.

FIG. 11 illustrates a perspective view of the conduit mount installed to the wire management feature of a rail-less solar panel mount.

FIG. 12 illustrates a side view of FIG. 11.

FIG. 13 illustrates the view of FIG. 11 showing a conduit installed in the conduit mount.

FIG. 14 illustrates front and rear perspective views of an alternate exemplary embodiment of the conduit mount shown in FIG. 7.

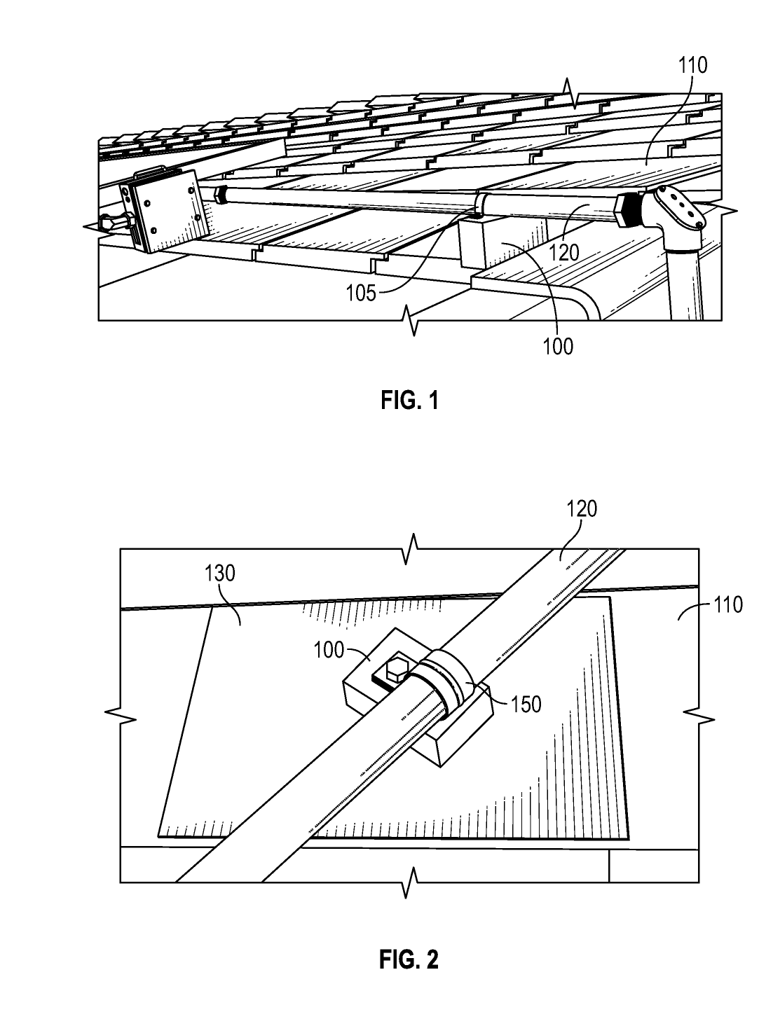

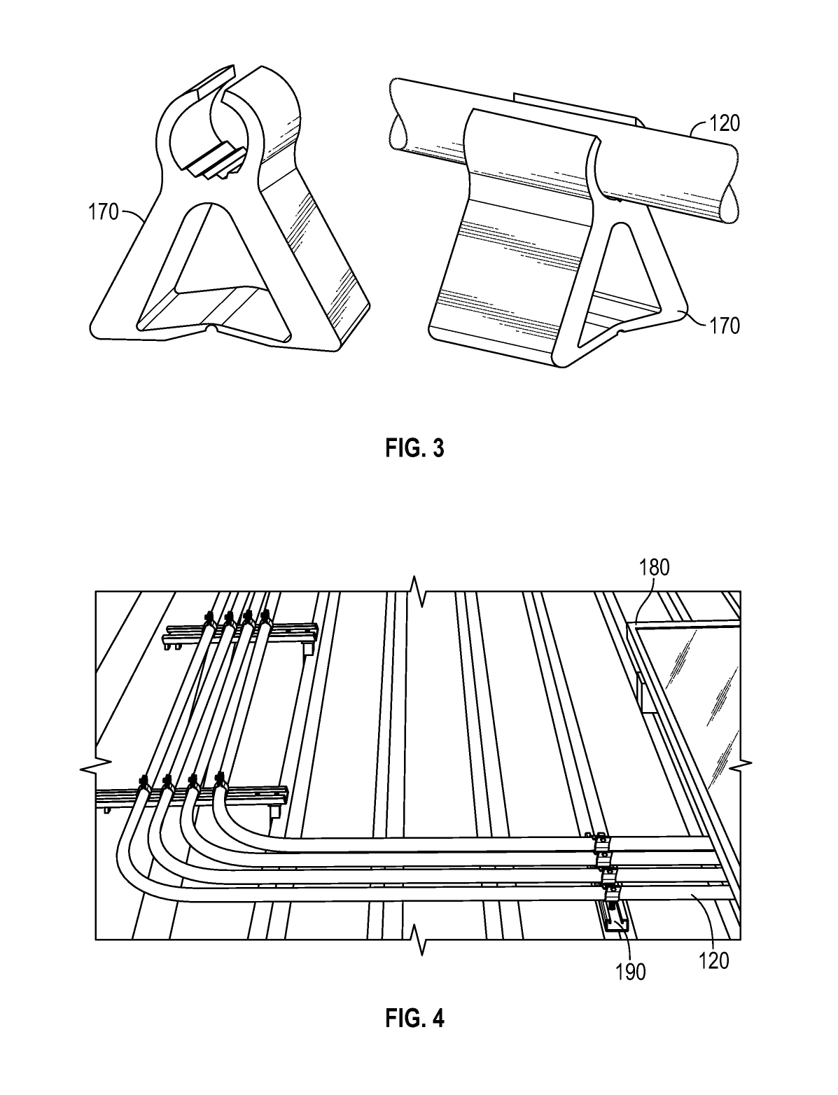

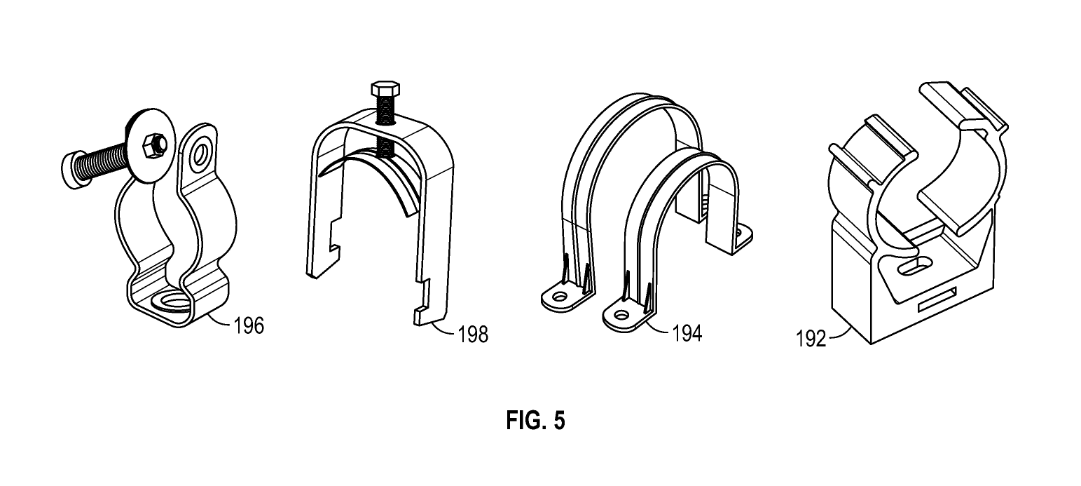

### DETAILED DESCRIPTION OF THE INVENTION

In the following description, and for the purposes of explanation, numerous specific details are provided to thoroughly understand the various aspects of the invention. It will be understood, however, by those skilled in the relevant arts, that the present invention may be practiced without these specific details. In other instances, known structures and devices are shown or discussed more generally in order to avoid obscuring the invention. In many cases, a description of the operation is sufficient to enable one to implement the various forms of the invention, particularly when the operation is to be implemented in software. It should be noted that there are many different and alternative configurations, devices and technologies to which the disclosed embodiments may be applied. The full scope of the invention is not limited to the example(s) that are described below.

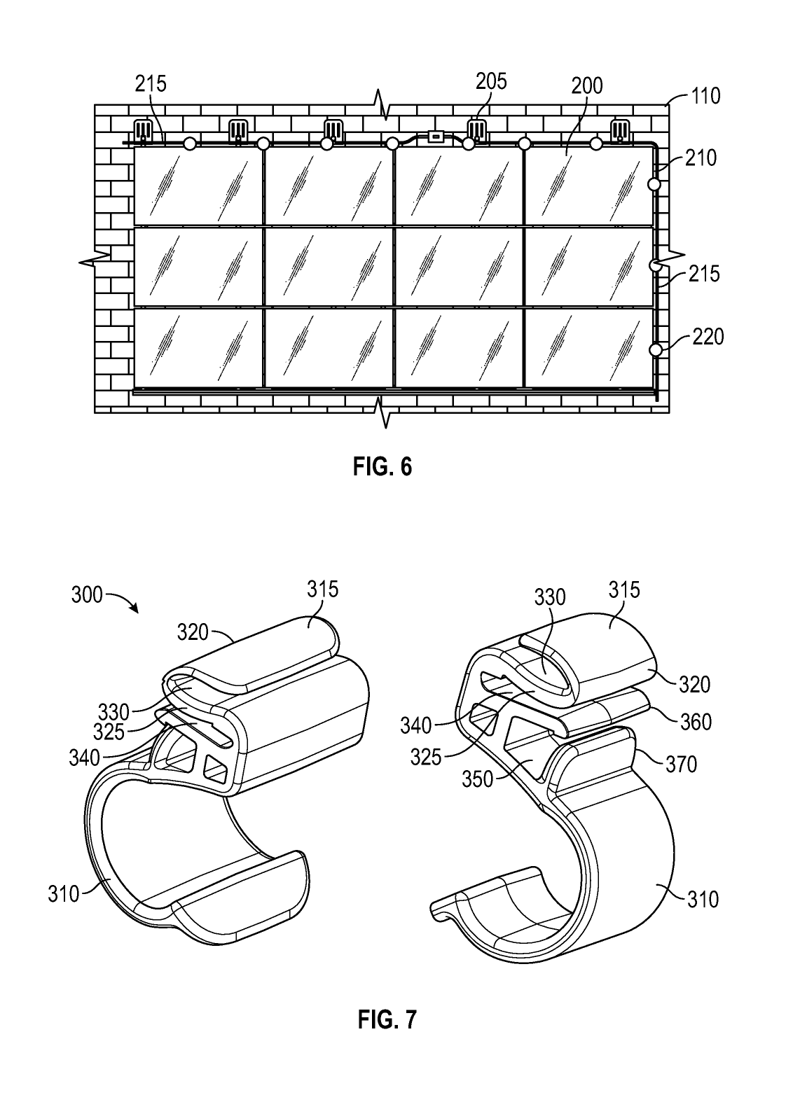

FIG. 6 shows a top view of a typical rail-less solar panel array structure 200 supported by a series of rail-less support mounts 205. Line 215 indicates a proposed conduit path with dots 215 indicating possible locations where a conduit 120 can be installed along the solar panel array structure 200.

FIG. 7 illustrates a front and rear perspective view of an exemplary embodiment of the conduit mount 300. The conduit mount 300 comprises a c-shaped retainer 310 on a lower end that receives and holds a generally cylindrically shaped conduit 120. It is understood that the shape of the retainer is not limited to c-shaped retainers and that other similar shapes of retainers could be used as well. The upper end includes a top lip 320 and a middle lip 360 that forms a flexible and resilient first mouth 340. The upper end also includes a lower lip 370 that when combined with the middle lip 360 forms a second mouth 350 beneath the first mouth 340. The upper end also includes a resilient s-shaped structure formed by top surface 315, top lip 320, and bottom surface 325 and opening 330.

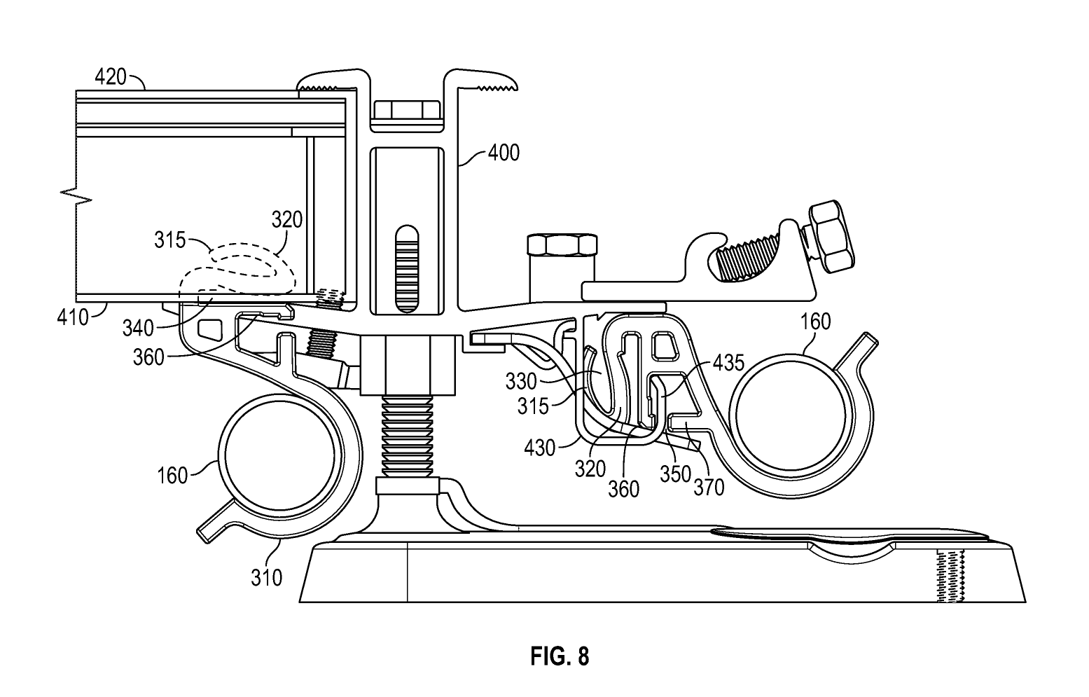

FIG. 8 illustrates an exemplary rail-less solar panel array support structure 400 that includes a solar panel frame 420 inserted on one side of the structure 400 and a wire management apparatus 430 on the opposite end of the rail-less support structure 400. The resiliency of the top lip 320 and middle lip 360 allows the first mouth 340 of the conduit mount 300 to be inserted onto a wide range of sizes and thicknesses of solar panel module flanges like the flange 410 shown in FIG. 8. The upper end can also be rotated 90 degrees so that upper end can be inserted into a wire management apparatus 430 by fitting the second mouth 350 over the terminating end 435 of the wire management apparatus 430 as shown in FIG. 8. The resiliency of the s-shaped structure enables the upper end to conform more snuggly to within the wire management apparatus 430.

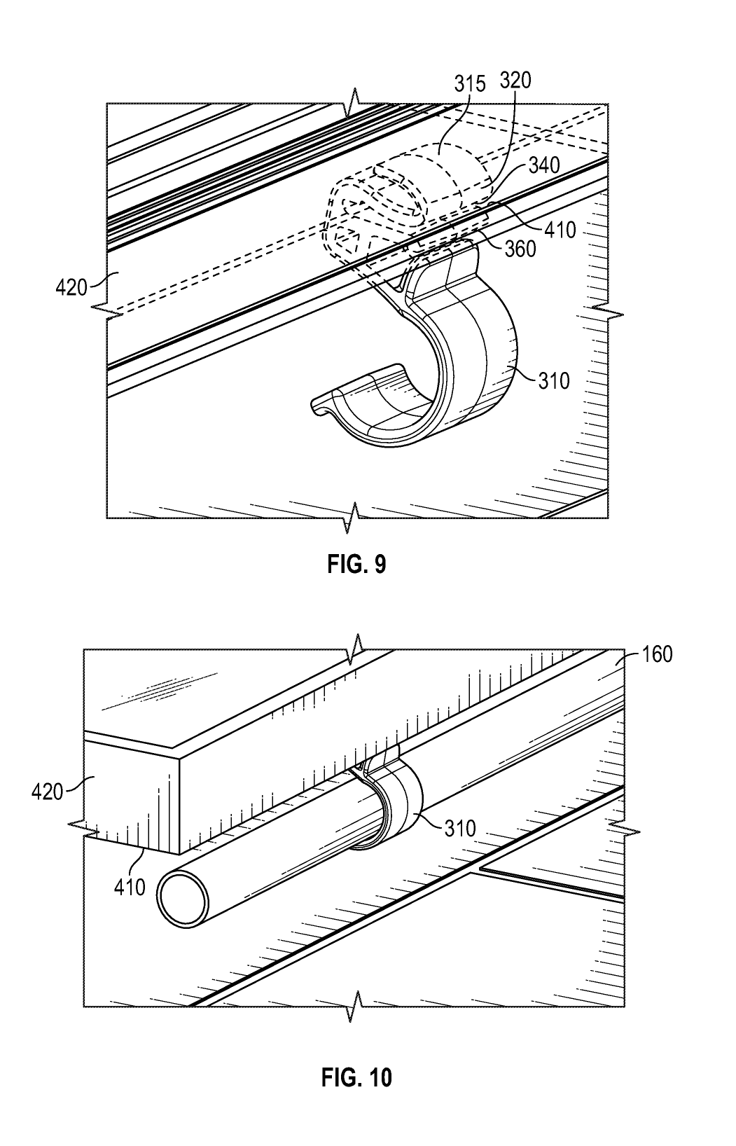

Each type of installation is a two-step process. When securing the conduit mount 300 to the solar panel module 420, the first step is to pull the conduit mount 420 onto the solar panel frame flange 410 through the first mouth 340 as shown in FIG. 9. The next step is to pull the conduit 160 into the c-shaped retainer 310 of the conduit mount 300 as shown in FIG. 10. No tools are typically needed to complete the installation.

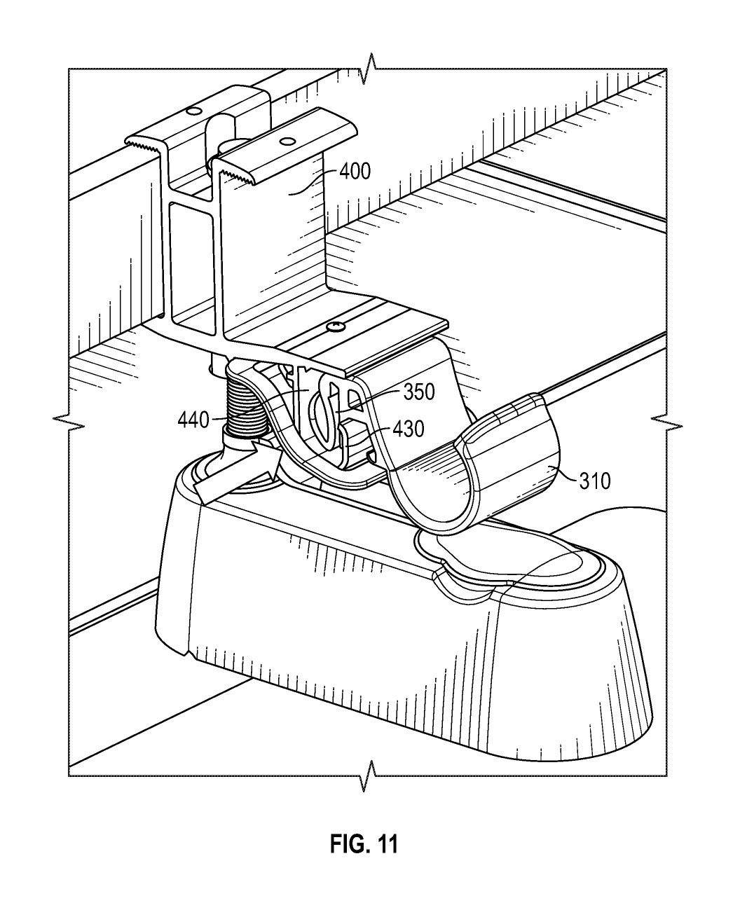

FIG. 11 shows a perspective view of the rail-less support structure 500 focusing on the side that includes the wire management apparatus 430. The conduit mount 300 can also be installed in a wire trough 440 of the wire management apparatus 430. The wire trough 440 in this exemplary embodiment is a J-shaped structure that includes the terminating end 435.

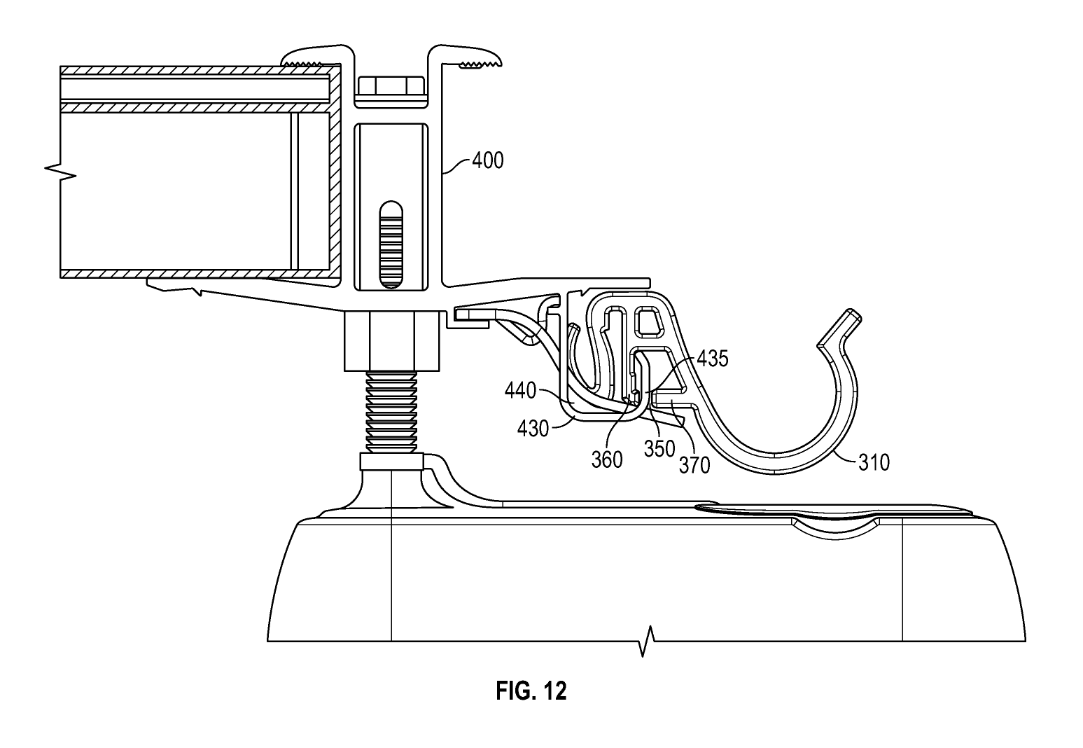

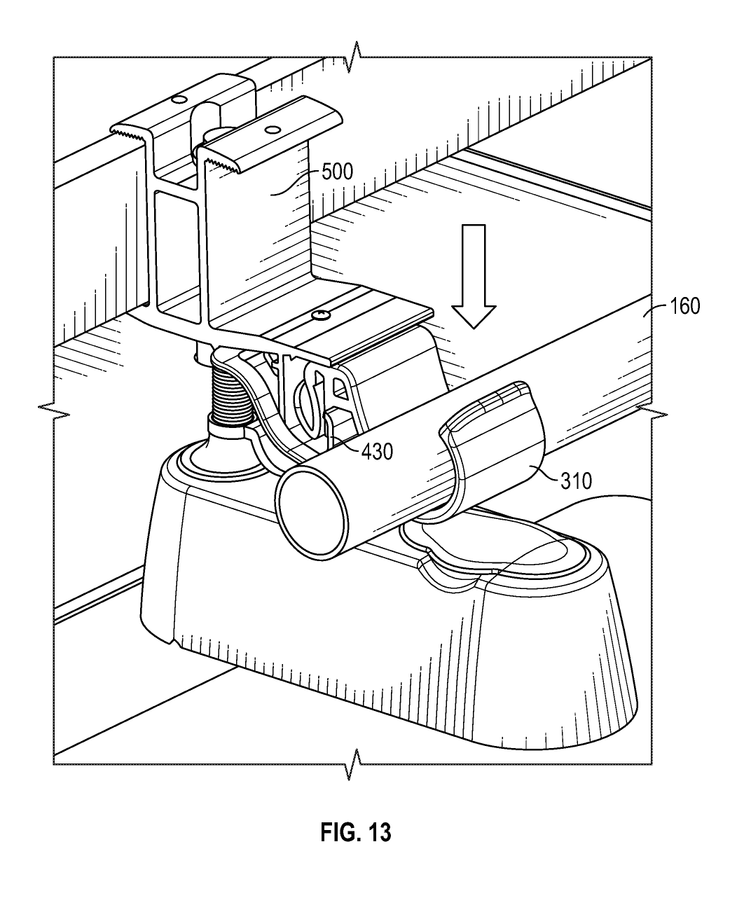

The installation is also a two-step process. The first step is sliding the conduit mount 300 into the wire trough as shown below in FIG. 12. This is accomplished by either inserting the upper end of the conduit mount 300 so that the terminating end 435 of the J-shaped structure fits into the second mouth 350 so that the s-shaped structure fits within the trough 440 and the middle lip 360 and the lower lip 370 fit snuggly on to the terminating end 435. The last step involves inserting the conduit 160 into the c-shaped retainer 310 as shown in FIG. 13. Essentially no tools are necessary to complete the installation process.

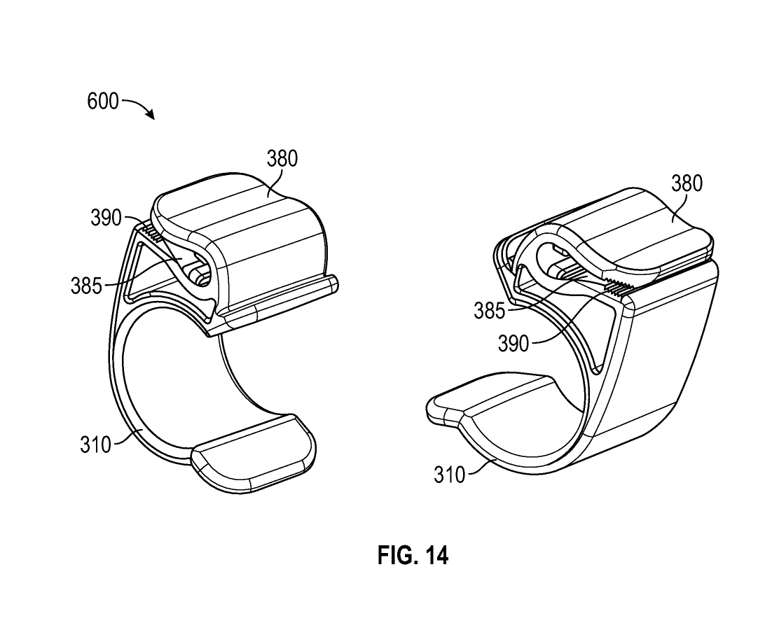

FIG. 14 illustrates a front and rear perspective view of an alternate exemplary embodiment of the conduit mount 600. In this embodiment, the conduit mount 600 provides for the conduit mount 600 to be installed solely on the solar panel module frame flange 410. The shape of the upper end has been slightly altered to provide only the clip function with a slot 385 and includes top lip 380 and bottom lip 390 to form the c-shaped mouth that is resilient so that it can be secured to the solar panel frame flange 410 without the need for any additional tools. The conduit mount 600 also includes the c-shaped retainer 310 for receiving the conduit 160.

What is claimed is:

1. A mounting assembly for securing a conduit to a solar panel frame comprising:
a. an upper end; the upper end comprises:
i. a top lip;
ii. a middle lip coupled to the top lip forming a first mouth;
iii. a lower lip coupled to the middle lip forming a second mouth beneath the first mouth
b. a lower end; such that the lower end is coupled to the upper end and comprises a conduit retainer.

2. The mounting assembly of claim 1 wherein the upper end further comprises a top surface extending from the top lip forming a resilient structure.

3. The mounting assembly of claim 2 wherein the resilient structure is generally s-shaped.

4. The mounting assembly of claim 1 wherein the first mouth is capable of receiving a solar panel frame flange.

5. The mounting assembly of claim 1 wherein the second mouth is capable of receiving a terminating end of a wire management structure that is secured to a rail-less solar panel support structure.

6. The mounting assembly of claim 1 wherein the conduit retainer is generally c-shaped for receiving a cylindrical conduit.

7. The mounting assembly of claim 1 wherein the first and second mouths are resilient.

8. A mounting assembly for securing a conduit to a solar panel frame comprising:
a. an upper end; the upper end comprises:
i. a top lip;
ii. a bottom lip coupled to the top lip forming a mouth;
b. a lower end; such that the lower end is coupled to the upper end and comprises a conduit retainer.

9. The mounting assembly of claim 8 wherein the first mouth is capable of receiving a solar panel frame flange.

10. The mounting assembly of claim 8 wherein the conduit retainer is generally c-shaped for receiving a cylindrical conduit.

11. The mounting assembly of claim 8 wherein the mouth is resilient.

12. A method of securing a conduit to a solar panel frame comprising the steps of:
a. coupling a first mouth of a mounting assembly for securing a conduit to a flange of a solar panel frame that comprises:
i. an upper end; the upper end comprises:
1. a top lip;
2. a middle lip coupled to the top lip forming the first mouth;
3. a lower lip coupled to the middle lip forming a second mouth beneath the first mouth
ii. a lower end; such that the lower end is coupled to the upper end and comprises a conduit retainer; and
b. Inserting a conduit into the conduit retainer.

13. The method of claim 12 wherein the upper end further comprises a top surface extending from the top lip forming a resilient structure.

14. The method of claim 13 wherein the resilient structure is generally s-shaped.

15. The method of claim 12 wherein the conduit retainer is generally c-shaped for receiving a cylindrical conduit.

16. The method of claim 12 wherein the first and second mouths are resilient.
